(19) United States
(12) Patent Application Publication
(10) Pub. No.: US 2019/0065361 A1
(43) Pub. Date: Feb. 28, 2019

(54) METHOD FOR WRITING DATA INTO FLASH MEMORY MODULE AND ASSOCIATED FLASH MEMORY CONTROLLER AND ELECTRONIC DEVICE

(71) Applicant: Silicon Motion Inc., Hsinchu County (TW)

(72) Inventors: Jen-Hung Liao, Hsinchu County (TW); Chia-Chin Hsieh, Taichung City (TW)

(21) Appl. No.: 15/865,269

(22) Filed: Jan. 9, 2018

(30) Foreign Application Priority Data
Aug. 31, 2017 (TW) 106129653

(51) Int. Cl. G06F 12/02; G11C 16/08; G11C 16/10; G11C 16/04; G11C 29/52; G06F 3/06

(52) U.S. Cl. CPC G06F 12/0246; G11C 16/08; G11C 16/10; G06F 2212/2022; G11C 29/52; G06F 3/064; G06F 3/0679; G11C 16/0483

(57) ABSTRACT

The present invention provides a method for writing data into a flash memory module, wherein each flash memory chip within the flash memory module includes a plurality of blocks, each block includes a plurality of pages, and the method includes: building a page-status table, wherein the page-status table records if at least a portion of pages within a specific block is/are damaged; when the data is to be written into the specific block, referring to the page-status table to determine if a specific page, which the data is intended to be written, is damaged; when the page-status table indicates that the specific page is not damaged, writing the data into the specific page; and when the page-status table indicates that the specific page is not damaged, not writing data into the specific page.

### BACKGROUND OF THE INVENTION

### 1. Field of the Invention

The present invention relates to flash memory, and more particularly, to a method for writing data into flash memory module and associated flash memory controller.

### 2. Description of the Prior Art

When power of a flash memory suddenly breaks down during a write operation, not only the page that is currently being written may be damaged, other pages that are located on a same word line with the page will also be damaged. For example, it is assumed that the above-mentioned flash memory is a triple-level cell (TLC) flash memory chip, and each word line in the TLC flash memory forms a least significant bit (LSB) page, a central significant bit (CSB) page and a most significant bit (MSB) page. If the LSB page on a word line encountered a sudden power-off during a write operation, the CSB page and the MSB page on the word line will also be damaged. Therefore, sudden power-off recovery (SPOR) procedures are crucial to maintain the data reliability of flash memory.

### SUMMARY OF THE INVENTION

Therefore, it is one object of the present invention to provide a method for writing data to a flash memory module, which can effectively continue subsequent SPOR procedure and data writing when the page has been damaged, thereby to solve problems in conventional art.

According to one embodiment of the present invention, a method for writing data into a flash memory module is provided. The flash memory module includes a plurality of flash memory chips, each flash memory chip within the flash memory module includes a plurality of blocks, and each block includes a plurality of pages. Each word line in the flash memory chip forms a plurality of pages. The method comprises: building a page-status table, wherein the page-status table records if at least a portion of pages within a specific block is damaged; referring to the page-status table to determine if a specific page which the data is intended to be written to is damaged; when the page-status table indicates that the specific page is not damaged, writing the data into the specific page; and when the page-status table indicates that the specific page is damaged, not writing data into the specific page.

According to another embodiment of the present invention, a flash memory controller is provided. The flash memory controller is arranged to access a flash memory module. The flash memory module includes a plurality of flash memory chips, each flash memory chip includes a plurality of blocks, and each block includes a plurality of pages, each word line in the flash memory chip forms a plurality of pages, the flash memory controller comprising: a read-only memory, a microprocessor and a memory. The read-only memory is arranged store a program code. The microprocessor is arranged to execute the program code to control access to the flash memory module. The memory is arranged to store a page-status table, wherein the page-status table records if at least a portion of pages within a specific block is damaged. When data is to be written to the specific block, the microprocessor refers to the page-status table to determine if a specific page which the data is intended to be written to is damaged; and when the page-status table indicates that the specific page is not damaged, the microprocessor writes the data into the specific page; and when the page-status table indicates that the specific page is damaged, the microprocessor does not write data into the specific page.

According to another embodiment of the present invention, an electronic device is provided. The electronic device comprises: a flash memory module and a flash memory controller. The flash memory module includes a plurality of flash memory chips, each flash memory chip includes a plurality of blocks, each block includes a plurality of pages, and each word line in the flash memory chip forms a plurality of pages. The flash memory controller is arranged to access the flash memory module and build a page-status table, wherein the page-status table records if at least a portion of pages within a specific block is damaged. When data from a host device needs to be written to the specific block, the flash memory controller refers to the page-status table to determine if a specific page which the data is intended to be written to is damaged; and when the page-status table indicates that the specific page is not damaged, the flash memory controller writes the data into the specific page; and when the page-status table indicates that the specific page is damaged, the flash memory controller does not write data into the specific page.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 illustrates a diagram of a memory device according to one embedment of the present invention.

FIG. 2 illustrates a block having TLC structure.

FIG. 3 illustrates a flow chart of writing data to a block of a flash memory according to one embedment of the present invention.

FIG. 4 illustrates a diagram showing a page-status table according to one embedment of the present invention.

FIG. 5 illustrates a diagram showing a rebuilt page-status table in response to a power-off event according to one embedment of the present invention.

### DETAILED DESCRIPTION

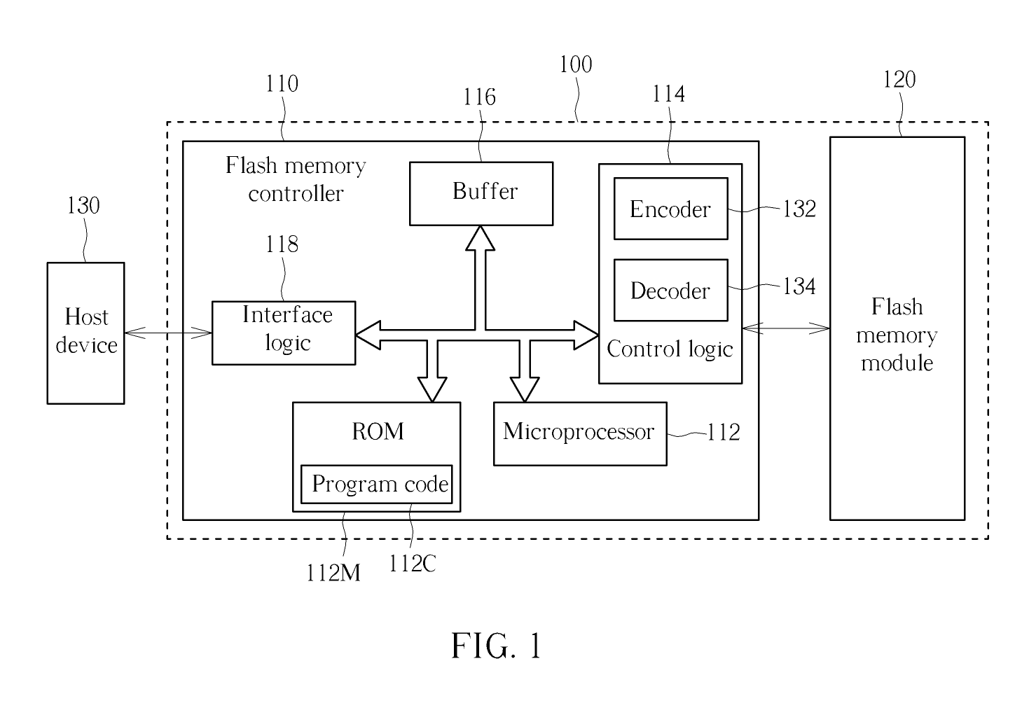

Please refer to FIG. 1, which illustrates a diagram of a memory device 100 according to one embodiment of the present invention. The memory device 100 includes a flash memory module 120 and a flash memory controller 110. The flash memory controller 110 is arranged to access the flash memory module 120. In this embodiment, the flash memory controller 110 includes a microprocessor 112, a read only memory (ROM) 112M, a control logic 114, a buffer 116 and an interface logic 118. The ROM 112M is arranged to store a program code 112C, and the microprocessor 112 is arranged to execute the program code 112C and control the access to the flash memory controller 120. The control logic 114 includes an encoder 132 and a decoder 134. The encoder 132 is arranged to encode data that is written to the flash memory module 120, thereby to generate corresponding checksum code (which is also called error correction code (ECC)), while the decoder 134 is arranged to decode data that is read from the flash memory module 120.

In a typical condition, the flash memory module 120 includes multiple flash memory chips, wherein each of flash memory chips includes multiple blocks. The controller (e.g. the flash memory controller 110 that controls the microprocessor 112 to execute the program code 112C) performs erase operations on the flash memory module 120 on a block basis. Further, one block can record a certain amount of pages, wherein the controller (e.g. the flash memory controller 110 that controls the microprocessor 112 to execute the program code 112C) performs write operations on the flash memory module 120 on a page basis. In this embodiment, the flash memory module 120 is a 3D NAND-type flash.

In practical, the flash memory controller 110 that controls the microprocessor 112 to execute the program code 112C can utilize its internal components for implementing various control operations. For example, utilizing the control logic 114 to control the access to the flash memory module 120 (especially access to at least one block or at least one page), utilizing the buffer 116 for necessary data buffering and utilizing the interface logic 118 to communicate with a host device 130. The buffer 116 can be implemented with random access memory (RAM), such as a static RAM. However, this is not intended to be a limitation of the present invention.

In one embodiment, the memory device 100 could be (but not limited to) portable memory device (such as memory card compliant with SD/MMC, CF, MS or XD standard). The host device 130 could be an electronic device that is connectable to the memory device, such as a cellular phone, a laptop, a desktop and so on. In another embodiment, the memory device 100 could be a solid state storage (SSD) or an embedded storage device that is compliant with UFS or EMMC standard. In such case, the memory device 100 is disposed in an electronic device, such as a cellular phone, a laptop, or a desktop. The host device 130 could be a processor of the electronic device.

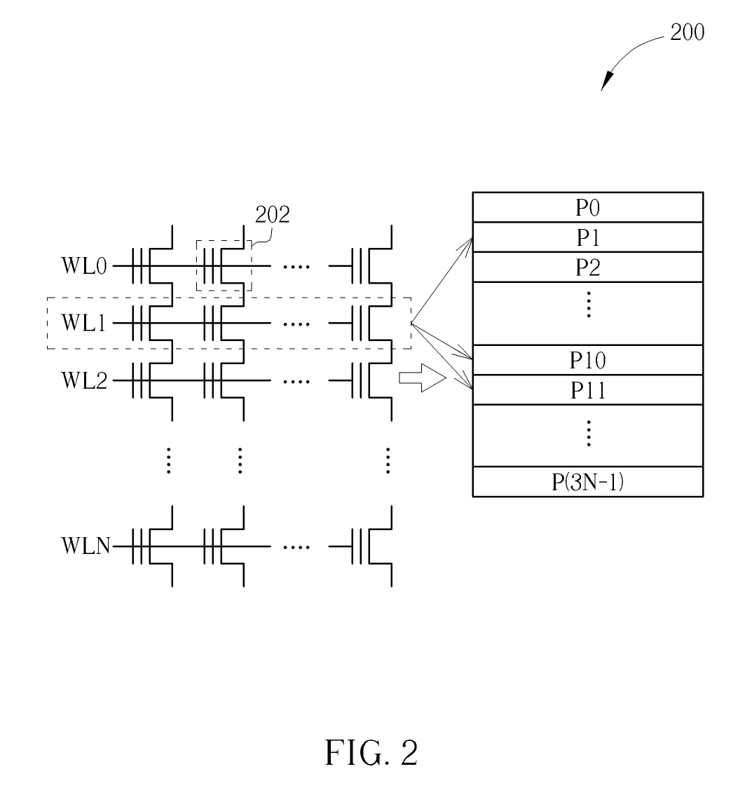

In this embodiment, the plurality of blocks included flash memory module 120 at least comprises multiple-level cell (MLC) blocks or triple-level cell (TLC) blocks. In the following embodiments, the TLC blocks will be taken as examples for illustrative purposes. Please refer to FIG. 2, which illustrates a block 200 of the flash memory module 120 according to one embodiment of the present invention. As illustrated by FIG. 2, the block 200 has the TLC structure. That is, the block 200 comprises N word lines WL0-WLN, and each word line forms three pages. Therefore, the block 200 comprises 3*N pages (P0˜P(3N-1)). Each cell in FIG. 2 (i.e. each floating-gate transistor 202) can record three bits, including a LSB bit, a CSB bit and a MSB bit. LSB bits stored in multiple cells on a word line forms a first page (LSB page) of the word line, CSB bits stored in multiple cells on the word line forms a second page (CSB page) of the word line and MSB bits stored in multiple cells on the word line forms a third page (MSB page) of the word line. In a general condition, three pages on a same word line may not have consecutive numbers. For example, the LSB bits stored in the multiple cells on the word line WL1 form page P1, the CSB bits stored in the multiple cells on the word line WL1 form page P10 and the MSB bits stored in the multiple cells on the word line WL1 form page P11.

In general, if the LSB page (i.e. page P1) on the word line WL1 is damaged because a sudden power-off occurs during a write operation, the CSB page (i.e. page P10) on the word line WL1 and the MSB page (i.e. page P11) on the word line WL1 will also be damaged. Thus, in one embodiment, after page P1 has been damaged, if it is still desired to write data to the following pages in the block 200, the flash memory controller 110 is operable to write dummy data from page P1 to page P11 and write valid data from page P12, such that data will not be written to pages P10 and P11 on the word line WL1. As mentioned above, such method could avoid data write error, but the pages P2-P9 are also wasted, however. Especially when the flash memory module 120 is a 3D NAND-type flash memory, distances between the LSB page, the CSB page and the MSB page are larger (i.e., difference between serial numbers of pages are also larger). Therefore, there will be more pages wasted in the 3D NAND-type flash memory.

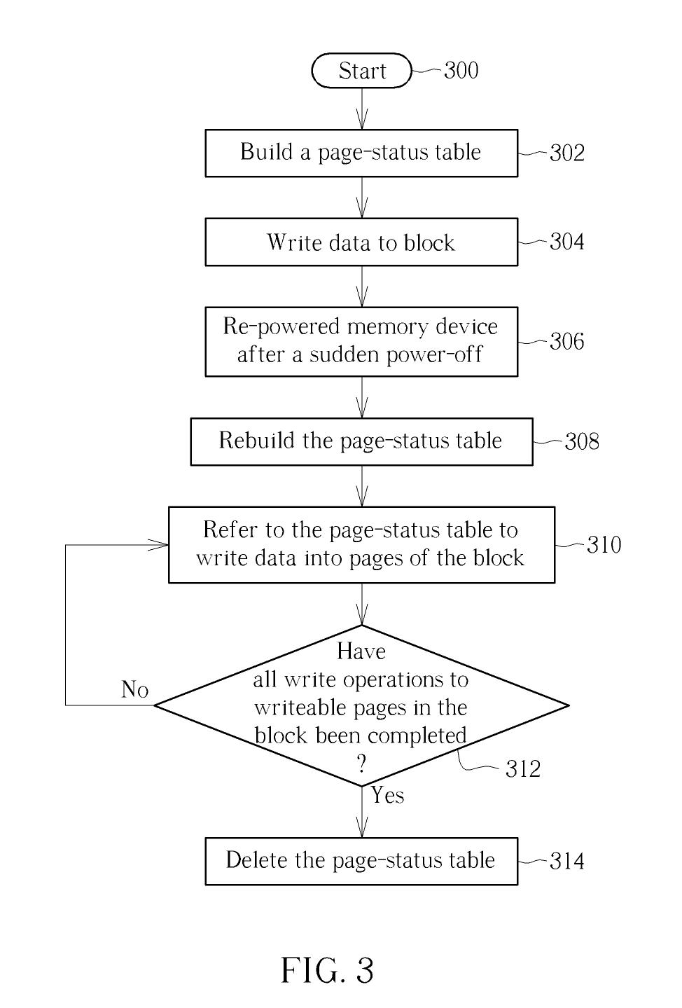

In order to address the above-mentioned problem that the pages are wasted due to a sudden power-off, the present invention further discloses the following embodiment, thereby to use pages in the block 200 in a more efficient way after a SPOR procedure. Please refer to FIG. 3, which illustrates a flow char of writing data to a block according to one embodiment of the present invention. In the following embodiment, the block 200 will be taken as an example for illustrative purposes. At step 300, the flow starts, where the flash memory controller 110 assign the block 200 to be a target block that is prepared for writing data. At step 302, the flash memory controller 110 builds a page-status table, which records if a page within the block 200 is damaged and stores the page-status table into buffer 116 temporarily. For example, as illustrated by FIG. 4, the page-status table could comprise multiple bits B0˜B(3N-1), which are used record whether pages P0˜P(3N-1) are damaged, respectively. For example, when the bit B0 has a value of “0”, it means page P0 is not damaged and when the bit B0 has a value of “1”, it means page P0 is damaged; when the bit B1 has a value of “0”, it means page P1 is not damaged and when the bit B1 has a value of “1”, it means page P1 is damaged, and so on. At step 302, as there is still no data written to the block 200, the value of each bit B0-B(3N-1) in the page-status table will be “0”, this means pages P0-P(3N-1) are not damaged.

The page-status table illustrated in FIG. 4 is merely intended for illustrative purposes, rather than a limitation. As long as damage state of the pages P0-P(3N-1) can be reflected, the page-status table may have alternative designs. Such alternative designs also fall within the scope of the present invention. In another embodiment of the present invention, the page-status table could only record pages that are damaged. That is, when there is still no data written to the block 200 in the beginning, the page-status table will not record damaged information regarding any pages. Instead, the page-status table only records information when a page is determined as damaged.

At step 304, the flash memory controller 110 receives a write command from a host device 130. At this time, the flash memory controller 110 starts to write data sequentially from page P0 according to the write command. If a sudden power-off occurs when the flash memory controller 110 is writing the data to page P1, the data in page P1 may have error and the page-status table stored in the buffer 116 is also lost.

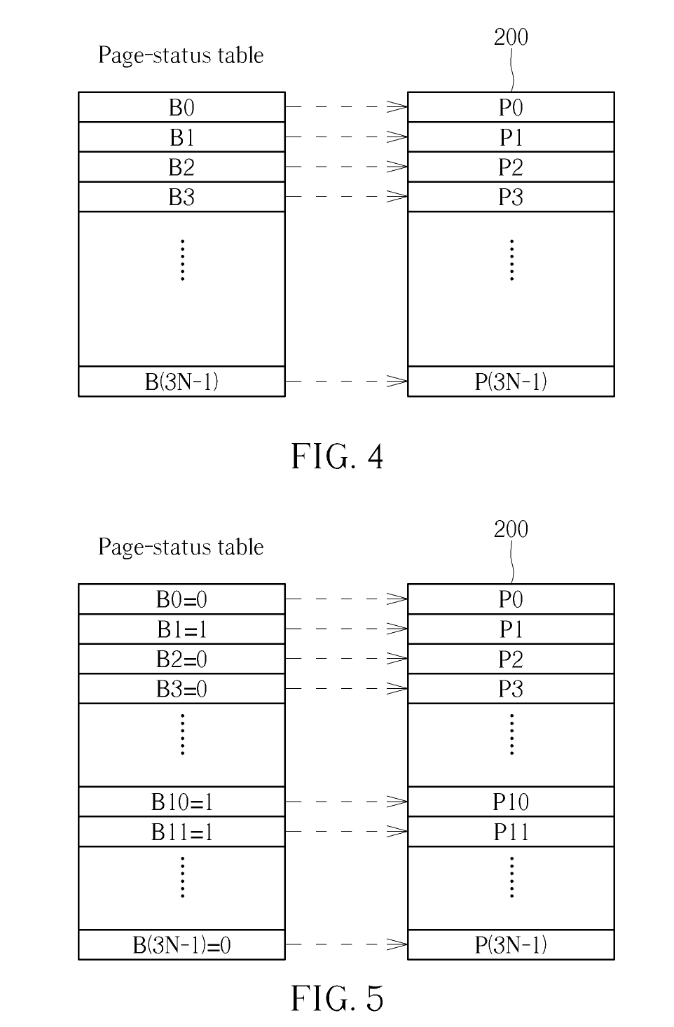

At step 306, the memory device 100 is re-powered, and the flash memory controller 110 and the flash memory module 120 perform initialization after powering-on. At step 308, the flash memory controller 110 rebuilds a page-status table corresponding to the block 200. During rebuilding the page-status table, the flash memory controller 110 firstly reads data from the pages which has been written to in the block 200 page by page and determines data qualities of these pages. With respect to any one of the pages which the data has been written to, if it is determined that the data quality of the page fails to meet a criterion, it is recorded in the page-status table the page is damaged and it is also recorded other pages which shares a same word line with the page are also damaged. For example, the flash memory controller 110 first read data stored in page P0 and use the decoder 134 to decode readout data (i.e., performing error correction operation). If the decoding is successful, it is determined that the data quality of page P0 meets the criteria. If the decoding is unsuccessful, it is determined that the data quality of page P0 fails to meet the criteria. In this embodiment, assuming that the data quality of page P0 meets the criteria, the value of the bit B0 in the rebuilt page-status table will be “0”. Accordingly, the flash memory controller 110 reads data in page P1 and utilizes the decoder 134 to decode the readout data. According to whether the decoding is successful, it is determined whether the data quality of page P1 meets the criteria. In this embodiment, if the data quality of page P1 fails to meet criterion due to the previous sudden power-off, the value of bit B1 in the rebuilt page-status table will be set as “1”. At this time, since the bit B1 corresponding to page P1 is marked as “1” (page damaged), the bits B10 and B111 corresponding to the pages P10 and P11, which share a same word line WL1 with page P1, are also marked as “1” (page damaged). On the other hand, as there is no data written into the pages P2-P9 and P12-P(3N-1), their corresponding bits B2-B9 and B12-B(3N-1) will remain and has the default value “0”. FIG. 5 illustrates a diagram shown the rebuilt page-status table according to this embodiment.

At step 310, the flash memory controller 110 refers to the page-status table to write the data into the block 200. Specifically, the flash memory controller 110 first refers to the bit B2 in the page-status table and since the value of the bit B2 is “0”, page P2 is not damaged. The flash memory controller 110 therefore directly writes the data into page P2. Afterwards, the flash memory controller 110 refers to bits B3-B9 in the page-status table and directly writes the data into pages P3-P9. Accordingly, before the flash memory controller 110 intends to write the data into a next page P10, the flash memory controller 110 refers to the bit B10 in the page-status table. Since the value of the bit B11 is “1”, it means page P10 has been damaged. The flash memory controller 110 will write dummy data into page P10. Then, the flash memory controller 110 refers to the bit B11 in the page-status table. Since the value of the bit B11 is “1” , which means page P11 has been damaged, the flash memory controller 110 also writes the dummy data to page P11. Accordingly, the flash memory controller 110 refers to the bit B12 in the page-status table. Since the value of bit B12 is “0” , which means page P12 has not been damaged, the flash memory controller 110 directly writes the data to page P12.

At step 312, the flash memory controller 110 determines whether all the write operations to the writeable pages in the block 200 have been completed. That is, it is determined whether data has been written in a last valid page (e.g. page P(3N-1)). If no, the flow goes to step 310, continuing written data on the block 200; otherwise, the flow goes to step 314.

At step 314, the flash memory controller 110 deletes the page-status table corresponding to the block 200 from the buffer 116.

After the writer operations on the block 200 has been completed, if the flash memory controller 110 needs to write data into another block in the following, the flow of FIG. 3 could be repeated to build a page-status table corresponding to the another block, as a reference for write operations.

It should be noted that the flash memory controller 110 may not continually write all pages in the block 200. Hence, when the block 200 does not need to record data temporarily and/or the space of the buffer 116 needs to be released for certain reasons, the flash memory controller 110 could store the page-status table corresponding to the block 200 into a block of the flash memory module 120 (e.g. the block 200 or a SLC block in the flash memory chip). When data needs to be written into the block 200 again, the flash memory controller 110 could read the page-status table from the flash memory module 120 again, and writes the data into the block 200 according to the page-status table.

In summary, in the method of writing data to the flash memory module of the present invention, as described in the above embodiments of FIGS. 3-5, when the flash memory controller 110 prepares to write data to a specific page (for example, the specific page is currently a blank page and with a lowest serial number in the block 200), the status of the specific page recorded in the page-status table is referred to first (i.e., damaged or not damaged) to determine if the specific page is writable. Therefore, only the pages marked as damaged in the block 200 will not be written with valid data, and other pages can be still used to store the data (i.e., only pages P1, P10, P11 in embodiments of FIGS. 3-5 will not be written with valid data), such that the pages in the block 200 can be fully utilized, thereby to enhance the usage of pages.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A method for writing data into a flash memory module, wherein the flash memory module includes a plurality of flash memory chips, each flash memory chip within the flash memory module includes a plurality of blocks, each block includes a plurality of pages, and each word line in the flash memory chip forms a plurality of pages, the method comprising:
building a page-status table, wherein the page-status table records if at least a portion of pages within a specific block is damaged;
referring to the page-status table to determine if a specific page which the data is intended to be written to is damaged;
when the page-status table indicates that the specific page is not damaged, writing the data into the specific page; and
when the page-status table indicates that the specific page is damaged, not writing data into the specific page.

2. The method of claim 1, further comprising:
when the page-status table indicates that the specific page is damaged, referring to the page-status table to write the data into a page that is closest to the specific page and not damaged.

3. The method of claim 1, wherein the step of building the page-status table comprises:
reading pages in the specific block which data has been written to;
determining data qualities of the pages which the data has been written to;
with respect to anyone of the pages which the data has been written to, if it is determined that the data quality of the page fails to meet a criterion, recording in the page-status table the page is damaged and directly recording other pages which shares a same word line with the page are also damaged.

4. The method of claim 3, wherein the specific block is a triple-level cell (TLC) block and each word line in the specific block form a least significant bit (LSB) page, a central significant bit (CSB) page and a most significant bit (MSB) page; and when any one of the LSB page, the CSB page and the MSB page fails to meet the criterion, other two of the LSB page, the CSB page and the MSB page are also marked as damaged in the page-status table.

5. The method of claim 1, wherein the specific block is the block that is currently preparing for data writing.

6. The method of claim 5, further comprising:
writing the page-status table into the flash memory module.

7. The method of claim 5, further comprising:
when all writable pages in the specific block have been written, deleting the page-status table.

8. The method of claim 5, wherein the page-status table comprises a plurality of bits, each bit corresponds to one page of the specific block, and two values of each bit indicate the corresponding page is damaged or not, respectively.

9. A flash memory controller, wherein the flash memory controller is arranged to access a flash memory module, the flash memory module includes a plurality of flash memory chips, each flash memory chip includes a plurality of blocks, each block includes a plurality of pages, and each word line in the flash memory chip forms a plurality of pages, the flash memory controller comprising:
a read-only memory arranged store a program code;
a microprocessor arranged to execute the program code to control access to the flash memory module; and
a memory arranged to store a page-status table, wherein the page-status table records if at least a portion of pages within a specific block is damaged;
wherein when data is to be written to the specific block, the microprocessor refers to the page-status table to determine if a specific page which the data is intended to be written to is damaged; and when the page-status table indicates that the specific page is not damaged, the microprocessor writes the data into the specific page; and when the page-status table indicates that the specific page is damaged, the microprocessor does not write data into the specific page.

10. The flash memory controller of claim 9, wherein when the page-status table indicates the specific page is damaged, the microprocessor refers to the page-status table to write the data into a page that is closest to the specific page and not damaged.

11. The flash memory controller of claim 9, wherein the page-status table is built by the microprocessor performing steps of:
reading pages in the specific block which data has been written to;
determining data qualities of the pages which the data has been written to;
with respect to anyone of the pages which the data has been written to, if it is determined that the data quality of the page fails to meet a criterion, recording in the page-status table the page is damaged and directly recording other pages which shares a same word line with the page are also damaged.

12. The flash memory controller of claim 11, wherein the specific block is a triple-level cell (TLC) block and each word line in the specific block form a least significant bit (LSB) page, a central significant bit (CSB) page and a most significant bit (MSB) page; and when any one of the LSB page, the CSB page and the MSB page fails to meet the criterion, other two of the LSB page, the CSB page and the MSB page are also marked as damaged in the page-status table.

13. The flash memory controller of claim 9, wherein the specific block is the block that is currently preparing for data writing.

14. The flash memory controller of claim 13, wherein the microprocessor writes the page-status table into the flash memory module.

15. The flash memory controller of claim 13, wherein when all writable pages in the specific block have been written, deleting the page-status table.

16. The flash memory controller of claim 9, wherein the page-status table comprises a plurality of bits, each bit corresponds to one page of the specific block, and two values of each bit indicate a corresponding page is damaged or not, respectively.

17. An electronic device, comprising:
a flash memory module, wherein the flash memory module includes a plurality of flash memory chips, each flash memory chip includes a plurality of blocks, each block includes a plurality of pages, and each word line in the flash memory chip forms a plurality of pages; and
a flash memory controller arranged to access the flash memory module and build a page-status table, wherein the page-status table records if at least a portion of pages within a specific block is damaged;
wherein when data from a host device needs to be written to the specific block, the flash memory controller refers to the page-status table to determine if a specific page which the data is intended to be written to is damaged; and when the page-status table indicates that the specific page is not damaged, the flash memory controller writes the data into the specific page; and when the page-status table indicates that the specific page is damaged, the flash memory controller does not write data into the specific page.

18. The electronic device of claim 17, wherein when the page-status table indicates the specific page is damaged, the flash memory controller refers to the page-status table to write the data into a page that is closest to the specific page and not damaged.

19. The electronic device of claim 17, wherein the page-status table is built by the flash memory controller performing steps of:
reading pages in the specific block which data has been written to;
determining data qualities of the pages which the data has been written to;
with respect to anyone of the pages which the data has been written to, if it is determined that the data quality of the page fails to meet a criterion, recording in the page-status table the page is damaged and directly recording other pages which shares a same word line with the page are also damaged.
